(19) United States
(12) Patent Application Publication
(10) Pub. No.: US 2009/0045441 A1
(43) Pub. Date: Feb. 19, 2009

(54) CMOS image sensor package

(75) Inventors: Young Do Kweon, Seoul (KR); Sung Yi, Suwon-si (KR); Hong-Won Kim, Suwon-si (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTRO-MECHANICS CO., LTD., Suwon (KR)

(21) Appl. No.: 12/078,175

(22) Filed: Mar. 27, 2008

(30) Foreign Application Priority Data
Aug. 17, 2007 (KR) 10-2007-0082912

(51) Int. Cl. H01L 31/113

(52) U.S. Cl. 257/291; 257/E31.084

(57) ABSTRACT

A CMOS image sensor package is disclosed. The CMOS image sensor package includes: a substrate, on which a pre-designed circuit pattern is formed, and in which a cavity is formed; a pixel array sensor, which is electrically connected with the circuit pattern and stacked on one side of the substrate; and a control chip, which is electrically connected with the circuit pattern and held within the cavity. According to certain aspects of the invention, the CMOS image sensor chip can be separated into the pixel array sensor and the control chip, with the control chip and passive components embedded in cavities formed in the substrate, so that the size of the chip mounted on the substrate may be reduced, and consequently the overall size of the CMOS image sensor package may be reduced.

### CROSS-REFERENCE TO RELATED APPLICATIONS

This application claims the benefit of Korean Patent Application No. 10-2007-0082912 filed with the Korean Intellectual Property Office on Aug. 17, 2007, the disclosure of which is incorporated herein by reference in its entirety.

### BACKGROUND

1. Technical Field

The present invention relates to a CMOS image sensor package.

2. Description of the Related Art

An image sensor chip is a semiconductor device that converts optical images into electrical signals. Examples of a typical image sensor component include the charge-coupled device (CCD) and the CMOS image sensor.

The CMOS image sensor utilizes a control circuit and a signal processing circuit positioned around MOS transistors, the number of which is equal to the number of pixels, and employs a switching technique using the MOS transistors to sequentially detect the output.

With the demand increasing for a greater variety of functions, smaller sizes, and lower costs in the digital camera module equipped in current mobile devices, much effort is being focused on reducing the size of the image sensor package. For the image sensor package using a CMOS image sensor, the attempts to reduce package size included methods employing the CLCC (ceramic leadless chip carrier) or the COB (chip-on-board) system.

FIG. 1 is a cross-sectional view illustrating a CMOS image sensor package according to the related art, FIG. 2 is a plan view illustrating a CMOS image sensor package according to the related art, and FIG. 3 is a diagram illustrating the structure of a CMOS image sensor package according to the related art. The conventional CMOS image sensor package 100 may include a CMOS image sensor chip 120, 160, which includes a pixel array 122, 162 and a control IC 124, 164 that processes the information outputted from the pixel array, and other passive components 140 mounted on a substrate 110, as well as wires 150 for electrical connection. The CMOS image sensor package 100 according to the related art may have the pixel array 122, 162 and the control IC 124, 164 implemented in one chip, with the other passive components, such as capacitors, inductors, resistors, etc., mounted on the substrate. As such, the overall size of the CMOS image sensor chip 120, 160 and the CMOS image sensor package 100 may be increased. Thus, there is a need for a CMOS image sensor package with a reduced size, to keep in step with the trends towards smaller products.

### SUMMARY

An aspect of the invention is to separate the pixel array sensor and the control chip in the CMOS image sensor chip and implant the control chip and passive components in cavities formed in the substrate, to provide a CMOS image sensor having a reduced size.

One aspect of the invention provides a CMOS image sensor package that includes: a substrate, on which a pre-designed circuit pattern is formed, and in which a cavity is formed; a pixel array sensor, which is electrically connected with the circuit pattern and stacked on one side of the substrate; and a control chip, which is electrically connected with the circuit pattern and held within the cavity.

The pixel array sensor may include a pixel array configured to receive light as input and produce electrical signals as output, where the pixel array can include a microlens, a color filter array disposed in correspondence with a position of the microlens, and a photodiode disposed in correspondence with a position of the color filter array.

The control chip may be configured to receive the electrical signals outputted by the pixel array sensor as input and produce video signals as output.

In certain embodiments, the CMOS image sensor package may further include a wire that electrically connects the circuit pattern and the pixel array sensor.

The CMOS image sensor package may also include a passive component that is electrically connected with the circuit pattern and held within the cavity.

According to certain aspects of the invention, the CMOS image sensor chip can be separated into the pixel array sensor and the control chip, with the control chip and passive components embedded in cavities formed in the substrate, so that the size of the chip mounted on the substrate may be reduced, and consequently the overall size of the CMOS image sensor package may be reduced.

Additional aspects and advantages of the present invention will be set forth in part in the description which follows, and in part will be obvious from the description, or may be learned by practice of the invention.

### BRIEF DESCRIPTION OF THE DRAWINGS

FIG. 1 is a cross-sectional view illustrating a CMOS image sensor package according to the related art.

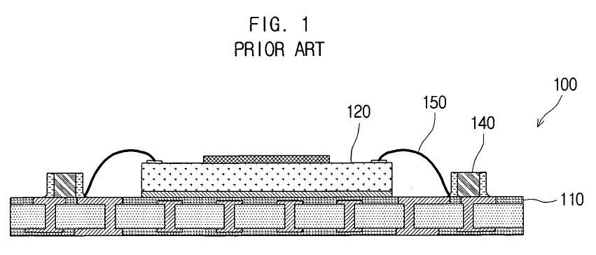

FIG. 2 is a plan view illustrating a CMOS image sensor package according to the related art.

FIG. 3 is a diagram illustrating the structure of a CMOS image sensor package according to the related art.

FIG. 4 is a cross-sectional view illustrating a CMOS image sensor package according to an embodiment of the present invention.

FIG. 5 is a plan view illustrating a CMOS image sensor package according to an embodiment of the present invention.

FIG. 6 is a schematic drawing illustrating a unit sensor in a pixel array sensor of a CMOS image sensor package according to an embodiment of the present invention.

### DETAILED DESCRIPTION

The CMOS image sensor package according to certain embodiments of the invention will be described below in more detail with reference to the accompanying drawings. Those components that are the same or are in correspondence are rendered the same reference numeral regardless of the figure number, and redundant explanations are omitted.

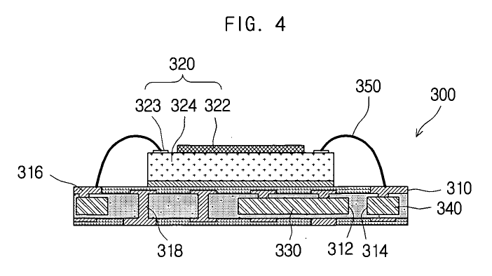

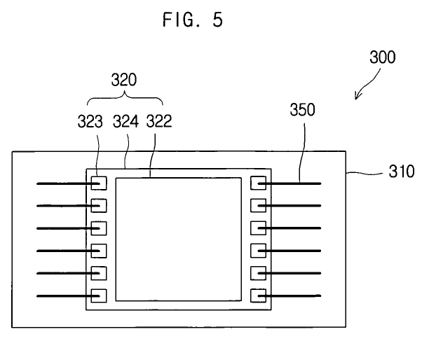

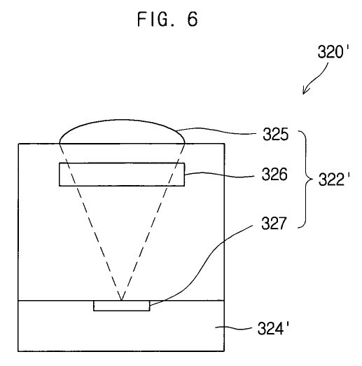

FIG. 4 is a cross-sectional view illustrating a CMOS image sensor package according to an embodiment of the present invention, FIG. 5 is a plan view illustrating a CMOS image sensor package according to an embodiment of the present invention, and FIG. 6 is a schematic drawing illustrating a unit sensor in a pixel array sensor of a CMOS image sensor package according to an embodiment of the present invention.

In FIGS. 4 to 6, there are illustrated a CMOS image sensor package 300, a substrate 310, a circuit pattern 316, vias 318, cavities 312, 314, a pixel array sensor 320, a pixel array unit sensor 320′, a pixel array 322, a unit pixel 322′, a silicon substrate 324, 324′, pads 323, a microlens 325, a color filter 326, a photodiode 327, a control chip 330, passive components 340, and wires 350.

In this embodiment, the CMOS image sensor chip may be separated into the pixel array sensor 320 and the control chip 330, where the control chip 330 and the passive components 340 may be embedded in cavities 312, 314 formed in the substrate 310, to provide a CMOS image sensor package 300 having a reduced size.

The substrate 310 can be a printed circuit board, in which a pre-designed circuit pattern 316 and vias 318 may be formed, and can have cavities 312, 314 formed inside. The pixel array sensor 320 may be stacked on one side of the substrate 310, while the control chip 330 and passive components 340 can be held in the cavities 312, 314 of the substrate 310. The pixel array sensor 320, control chip 330, passive components 340, and circuit pattern 316 on the substrate 310 can be electrically connected with one another for operation.

The pixel array sensor 320, control chip 330, and various components including passive components 340, etc., all of which may be electrically connected with one another, can be packaged within the substrate 310. Thus, the CMOS image sensor package 300 may be equipped in an electronic product, such as a cell phone and a digital camera, etc., in a more convenient manner.

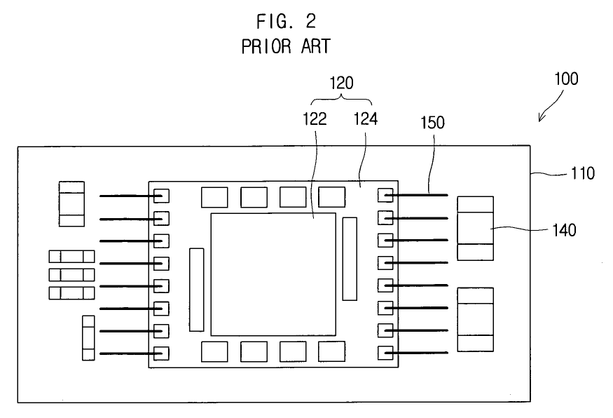

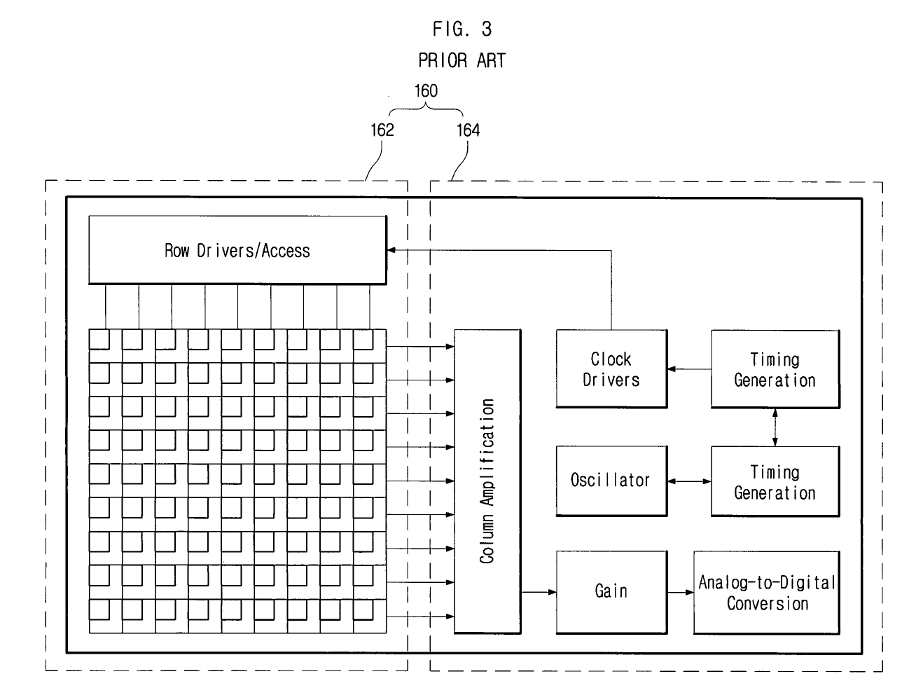

The CMOS image sensor chip can have the pixel array sensor 320 and the control chip 330 separated from each other. That is, whereas in the related art, both the pixel array 162 (FIG. 2) and the control IC 164 (FIG. 2) are formed on the CMOS image sensor chip 160 (FIG. 3), in this embodiment, the CMOS image sensor chip may be structured such that the pixel array sensor 320, which includes the pixel array 322, and the control chip 330, which includes the control IC, are separated from each other. As such, the pixel array sensor 320 can be produced separately, whereby the yield of pixel array sensors 320 per wafer may be increased, and the unit cost for production may be decreased.

The pixel array sensor 320 may be electrically connected by wires 350 to the circuit pattern 316 of the substrate 310, and may be stacked on one side of the substrate 310. That is, either end of a wire 350 can be joined respectively to a pad 323 formed on the pixel array sensor 320 and to the circuit pattern 316 formed on the substrate 310, to electrically connect the substrate 310 and the pixel array sensor 320. Thus, the control chip 330 and passive components 340, etc., electrically connected with the circuit pattern 316 of the substrate 310 may interact with the pixel array sensor 320, allowing the arrangement to operate as a whole as a CMOS image sensor package 300.

The pixel array sensor 320 may include a pixel array 322 formed on a silicon substrate 324, and the area occupied by the control chip in the conventional image sensor package can be reduced, allowing for use even in portable-sized electronic products such as cell phones and digital cameras, etc.

The pixel array 322 is a set of unit pixels 322′. The pixel array 322 may receive light, convert it into electrical signals, and output the electrical signals to the control chip 330, and may be composed of a plurality of microlenses 325, a color filter array, which is a set of color filters 326, and a plurality of photodiodes 327, formed on the silicon substrate 324.

That is, as illustrated in the pixel array sensor's unit sensor 320′ in FIG. 6, the unit pixel 322′, which forms a part of the pixel array 322, may include a microlens 325, color filter 326, and photodiode 327, formed on a silicon substrate 324′.

The microlens 325 may receive light from the exterior, which may pass the color filter 326 to reach the photodiode 327. In order that the light may reach the photodiode 327 with greater effectiveness, the focus of the microlens 325 may be concentrated onto the photodiode 327.

The color filter 326 may be disposed below the microlens 325 in correspondence with the position of the microlens 325. From the light received at the microlens 325, the color filter 326 may detect one of a red, blue, and green color, which may be converted by the photodiode 327 into an electrical signal.

The photodiode 327 may be a kind of semiconductor diode, which utilizes the phenomenon that, when light contacts the P-N junction of a semiconductor, a carrier is generated, which creates an electrical current or an electromotive force. The photodiode 327 may convert the light which has passed through the microlens 325 and the color filter 326 into an electrical signal, which may be outputted to the control chip 330.

The control chip 330 may be electrically connected with the circuit pattern 316 of the substrate 310, and may be held in a cavity 312 to be installed in the substrate 310. The control chip 330 can receive the electrical signals outputted from the pixel array sensor 320, and then convert the electrical signals into video signals for output.

In other words, the control chip 330, which can be embedded in a cavity 312 of the substrate 310, may be electrically connected with the pixel array sensor 320 and the passive components 340 by the pre-designed pattern and vias 318 formed on/in the substrate 310, so that the electrical signals converted at the photodiodes 327 of the pixel array 322 may undergo analog processing and digital conversion, to be outputted as video signals.

The control chip 330 may include a control IC, such as a CDS (correlated double sampler) and ADC (analog-digital converter), etc., where the electrical signals outputted from the pixel array sensor 320 may pass through the control IC, such as the CDS and ADC, to be converted to digital signals, i.e. video signals.

By separating the control IC portion of a conventional CMOS image sensor chip into an independent control chip 330 and embedding it in a cavity 312 in the substrate 310, the size of the chip stacked on the substrate 310 may be reduced, allowing easier application to portable-size electronic products.

The passive components 340 may be electrically connected to the circuit pattern 316 of the substrate 310, and may be held in cavities 314 formed inside the substrate 310 to be installed in the substrate 310. For example, passive components 340 such as capacitors, inductors, resistors, etc., can be equipped within the cavities 314, and can be electrically connected with the pixel array sensor 320 and the control chip 330 by the circuit pattern 316 and vias 318 formed on/in the substrate 310.

By embedding the passive components 340 in the cavities 314, the area of the substrate 310 in which passive components 340 are mounted can be reduced. As such, the size of the substrate 310 can be reduced, and consequently, the overall size of the CMOS image sensor package 300 may also be reduced. Thus, the CMOS image sensor package 300 may be equipped in a portable-size electronic product, such as a cell phone and a digital camera, etc., with greater convenience.

In this embodiment, the CMOS image sensor chip may be separated into the pixel array sensor 320 and the control chip 330, where the control chip 330 and passive components 340 may be embedded in cavities 312, 314 formed in the substrate 310. This can reduce the size of the chip mounted on the substrate 310, while at the same time eliminating problems in solder joints with regards the passive components 340. As such, the size of the substrate 310 may be reduced, so that consequently the overall size of the CMOS image sensor package 300.

While the spirit of the invention has been described in detail with reference to particular embodiments, the embodiments are for illustrative purposes only and do not limit the invention. It is to be appreciated that those skilled in the art can change or modify the embodiments without departing from the scope and spirit of the invention.

What is claimed is:

1. A CMOS image sensor package comprising:
a substrate having a pre-designed circuit pattern formed thereon and having a cavity formed therein;
a pixel array sensor electrically connected with the circuit pattern and stacked on one side of the substrate; and
a control chip electrically connected with the circuit pattern and held within the cavity.

2. The CMOS image sensor package of claim 1, wherein the pixel array sensor comprises:
a pixel array configured to receive light as input and produce electrical signals as output,
the pixel array comprising a microlens, a color filter array disposed in correspondence with a position of the microlens, and a photodiode disposed in correspondence with a position of the color filter array.

3. The CMOS image sensor package of claim 2, wherein the control chip is configured to receive the electrical signals outputted by the pixel array sensor as input and produce video signals as output.

4. The CMOS image sensor package of claim 1, further comprising:
a wire electrically connecting the circuit pattern with the pixel array sensor.

5. The CMOS image sensor package of claim 1, further comprising:
a passive component electrically connected with the circuit pattern and held within the cavity.
